(19) United States
(12) Patent Application Publication
(10) Pub. No.: US 2021/0261413 A1
(43) Pub. Date: Aug. 26, 2021

(54) AGGREGATE BORON NITRIDE PARTICLES, BORON NITRIDE POWDER, PRODUCTION METHOD FOR BORON NITRIDE POWDER, RESIN COMPOSITION, AND HEAT DISSIPATION MEMBER

(71) Applicant: DENKA COMPANY LIMITED, Tokyo (JP)

(72) Inventors: Go TAKEDA, Omuta-city (JP); Yoshitaka TANIGUCHI, Omuta-city (JP)

(73) Assignee: DENKA COMPANY LIMITED, Tokyo (JP)

(21) Appl. No.: 17/252,920

(22) PCT Filed: Jun. 27, 2019
(86) PCT No.: PCT/JP2019/025753

§ 371 Date: Dec. 16, 2020

(30) Foreign Application Priority Data
Jun. 29, 2018 (JP) 2018-124451

(51) Int. Cl. C01B 21/064; C08K 3/38; C09K 5/14

(52) U.S. Cl. CPC C01B 21/0648; C08K 3/38; C09K 5/14; C01P 2002/76; C01P 2004/50; C08K 2201/005; C01P 2004/61; C01P 2006/11; C01P 2002/72; C08K 2003/385; C01P 2004/02; C01P 2004/51

(57) ABSTRACT

An aspect of the present disclosure provides aggregate boron nitride particles in which primary hexagonal boron nitride particles are aggregated, wherein an average value of an area proportion of the primary particles in a cross section is 45% or more, a standard deviation of the area proportion of the primary particles in a cross section is less than 25, and a crushing strength is 8.0 MPa or more.

### TECHNICAL FIELD

The present disclosure relates to aggregate boron nitride particles, a boron nitride powder, a production method for boron nitride powder, a resin composition, and a heat dissipation member.

### BACKGROUND ART

In heat-generating electronic components such as power devices, transistors, thyristors, and CPUs, how to efficiently dissipate heat generated during use is an important issue. In the related art, regarding measures for heat dissipation, (1) making an insulation layer of a printed wiring board on which a heat-generating electronic component is mounted highly thermally conductive or (2) attaching a heat-generating electronic component or a printed wiring board on which a heat-generating electronic component is mounted to a heatsink with an electrically insulating thermal interface material therebetween is generally performed. For the insulation layer of the printed wiring board and the thermal interface material, a resin composition in which a ceramic powder is filled into a silicone resin or an epoxy resin is used.

In recent years, as the speed and integration of circuits in heat-generating electronic components has increased and the density of heat-generating electronic components being mounted on printed wiring boards has increased, the heat generation density inside electronic devices has increased year after year. Therefore, there is demand for a ceramic powder having a higher thermal conductivity than before.

In view of the background described above, a hexagonal boron nitride powder having excellent properties for an electrically insulating material such as high thermal conductivity, improved insulation properties, and a low relative dielectric constant has been focused on.

However, hexagonal boron nitride particles have a thermal conductivity in the in-plane direction (a axis direction) of 400 W/(m·K) and a thermal conductivity in the thickness direction (c axis direction) of 2 W/(m·K), and have a large anisotropy in the thermal conductivity derived from the crystal structure and the scaly shape. In addition, when a hexagonal boron nitride powder is filled into a resin, particles are aligned and oriented in the same direction.

Therefore, for example, when a thermal interface material is produced, the in-plane direction (a axis direction) of hexagonal boron nitride particles and the thickness direction of the thermal interface material are perpendicular to each other, and the high thermal conductivity of hexagonal boron nitride particles in the in-plane direction (a axis direction) cannot be sufficiently utilized.

Patent Literature 1 proposes that the in-plane direction (a axis direction) of hexagonal boron nitride particles be oriented in the thickness direction of a highly thermally conductive sheet and the high thermal conductivity of hexagonal boron nitride particles in the in-plane direction (a axis direction) can be utilized.

However, in the related art described in Patent Literature 1, there are problems that (1) it is necessary to laminate an oriented sheet in the next process and a production process tends to become complicated and (2) it is necessary to cut thinly into a sheet after laminating and curing, and it is difficult to secure the dimensional accuracy of the thickness of the sheet. In addition, since hexagonal boron nitride particles have a scaly shape, and cause an increase in viscosity and deterioration of fluidity when filled into a resin, it is difficult to fill the resin with boron nitride particles with a high density.

In order to address these problems, boron nitride powders having various shapes in which the anisotropy of thermal conductivity of hexagonal boron nitride particles is reduced have been proposed.

Patent Literature 2 proposes use of boron nitride powder in which hexagonal boron nitride particles as primary particles are not oriented in the same direction but are aggregated, and it was reported that the anisotropy of thermal conductivity could be reduced. In addition, in other related art in which an aggregated boron nitride is produced, a spherical boron nitride produced by a spray drying method (Patent Literature 3), an aggregate boron nitride produced using boron carbide as a raw material (Patent Literature 4), and an aggregated boron nitride produced by repeatedly performing pressing and crushing (Patent Literature 5) are also known. However, in reality, in these cases, the density of boron nitride in the aggregated particles and the uniformity of primary particles are not sufficient, and it was not possible to obtain aggregated boron nitride having excellent heat dissipation and insulation characteristics.

### CITATION LIST

### Patent Literature

[Patent Literature 1] Japanese Unexamined Patent Publication No. 2000-154265

[Patent Literature 2] Japanese Unexamined Patent Publication No. H9-202663

[Patent Literature 3] Japanese Unexamined Patent Publication No. 2014-40341

[Patent Literature 4] Japanese Unexamined Patent Publication No. 2011-98882

[Patent Literature 5] Japanese Unexamined Patent Publication No. 2007-502770

### SUMMARY OF INVENTION

### Technical Problem

In the above related art, since the density of boron nitride (the average value of a proportion of primary particles) contained inside the produced aggregated particles is not sufficiently high, the structure of primary particles is not sufficiently uniform, and stable and improved insulation characteristics and improved heat dissipation characteristics could not be achieved.

An object of the present disclosure is to provide an aggregate boron nitride powder having excellent insulation properties and thermal conductivity. An object of the present disclosure is to provide a boron nitride powder having excellent insulation properties and thermal conductivity and a method for producing the same.

### Solution to Problem

The inventors conducted extensive studies, and as a result, found that aggregate boron nitride particles which have a sufficiently high density of primary boron nitride particles contained therein and have a uniform primary structure can be produced by a specific production method. In addition, the inventors found that the aggregate boron nitride particles have low anisotropy and a high tap density, and a boron nitride powder containing the aggregate boron nitride particles has excellent insulation properties and thermal conductivity, and completed the present invention.

Specifically, one aspect of the present disclosure can be provided as follows.

(1) Aggregate boron nitride particles in which primary hexagonal boron nitride particles are aggregated, wherein an average value of an area proportion of the primary particles in a cross section is 45% or more, a standard deviation of the area proportion of the primary particles in a cross section is less than 25, and a crushing strength is 8.0 MPa or more.
(2) The aggregate boron nitride particles according to (1), wherein the average value of an area proportion of the primary particles in a cross section is 50 to 85%.
(3) The aggregate boron nitride particles according to (1) or (2), wherein the standard deviation of the area proportion of the primary particles in a cross section is 20 or less.
(4) The aggregate boron nitride particles according to any one of (1) to (3), wherein the standard deviation of the area proportion of the primary particles in a cross section is 15 or less.
(5) A boron nitride powder comprising the aggregate boron nitride particles according to any one of (1) to (4).
(6) A boron nitride powder having an average particle size of 20 to 100 μm, an orientation index of 12 or less determined from powder X-ray diffraction, and a tap density of 0.85 g/cm³ or more.
(7) A production method for a boron nitride powder containing aggregate boron nitride particles, including: firing boron carbide having a carbon content of 18.0 to 21.0 mass % under a nitrogen atmosphere at 1,800° C. or higher and 0.6 MPa or more to obtain a first fired product; firing the first fired product under a condition of an oxygen partial pressure of 20% or more to obtain an oxidized powder; mixing the oxidized powder and a boron source vacuum-impregnating the oxidized powder with a boron-containing liquid phase component; heating and firing the oxidized powder impregnated with the liquid phase component under a nitrogen atmosphere at 1,800° C. or higher to obtain a second fired product; and pulverizing the second fired product is pulverized to obtain a boron nitride powder containing an aggregate boron nitride powder.
(8) A resin composition comprising the boron nitride powder according to (5) or (6), and a resin.
(9) A heat dissipation member comprising a cured product of the resin composition according to (8).

### Advantageous Effects of Invention

According to the present disclosure, it is possible to provide an aggregate boron nitride powder having excellent insulation properties and thermal conductivity. According to the present disclosure, it is also possible to provide a boron nitride powder having excellent insulation properties and thermal conductivity and a method for producing the same.

### BRIEF DESCRIPTION OF DRAWINGS

FIG. 1 is a cross-sectional image of aggregate boron nitride particles of Example 1 observed using an electron microscope.

FIG. 2 is a cross-sectional image of boron nitride particles of Comparative Example 1 observed using an electron microscope.

### DESCRIPTION OF EMBODIMENTS

<Aggregate Boron Nitride Particles>

“Aggregate boron nitride particles” and “aggregate particles” in this specification refer to boron nitride particles in which primary scaly hexagonal boron nitride particles (hereinafter simply referred to as “primary particles” in some cases) are aggregated to form an aggregation. Aggregate boron nitride particles according to one embodiment of the present disclosure are aggregate boron nitride particles in which primary hexagonal boron nitride particles are aggregated and satisfy all of the following conditions (A) to (C).

(A) The average value of an area proportion of primary particles in a cross section of the aggregate boron nitride particles is 45% or more. The average value of the area proportion of primary particles in a cross section of the aggregate boron nitride particles is preferably 50% or more and more preferably 55% or more. The upper limit of the average value of the area proportion is not particularly limited and may be, for example, less than 90%, 85% or less or less than 85%. Here, since aggregate boron nitride particles are aggregates of primary boron nitride particles, it is generally difficult to produce 85% or more of aggregate boron nitride particles. When the above average value of the area proportion is less than 45%, the inside of aggregate boron nitride particles has a sparse structure, and thus the thermal conductivity of the aggregate boron nitride particles tends to decrease. The average value of the area proportion of primary particles in a cross section of the aggregate boron nitride particles can be adjusted within the above range, and may be, for example, 45 to 90% or 50 to 85%.

(B) The standard deviation of the area proportion of primary particles in a cross section of the aggregate boron nitride particles is less than 25. The standard deviation of the area proportion of primary particles in a cross section of the aggregate boron nitride particles is preferably 20 or less, more preferably 15 or less, and still more preferably less than 15. When the above standard deviation exceeds 25, the degrees of penetration of the resin in the aggregate boron nitride particles may be different, insufficient penetration may cause voids and the like, insulation properties (particularly, dielectric breakdown voltage) deteriorate, and insulation variation also increases in correlation with the degree of the standard deviation. A method for increasing a pressing pressure during molding is conceivable in order to allow the resin to sufficiently penetrate into aggregate boron nitride particles. However, when the pressing pressure is too high, the aggregate boron nitride particles may collapse and the primary particles may become oriented, which results in a decrease in thermal conductivity.

The average value and standard deviation of “the area proportion of primary particles in a cross section” of the aggregate boron nitride particles in this specification mean values determined by the methods described in examples.

(C) The crushing strength is 8.0 MPa or more. The crushing strength of the aggregate boron nitride particles is preferably 10.0 MPa or more, and more preferably 12.0 MPa or more. When the crushing strength is less than 8.0 MPa, problems such as collapse of the aggregate boron nitride particles due to stress during kneading with the resin or during pressing, and a decrease in thermal conductivity occur. The “crushing strength” in this specification means the crushing strength (single granule crush strength) obtained according to JIS R1639-5: 2007.

When the crushing strength of the aggregate boron nitride particles is 8.0 MPa or more, it is possible to reduce destruction of the aggregate boron nitride particles in a pulverizing process, a heat dissipation member producing process, and the like. Therefore, the boron nitride powder containing the aggregate boron nitride particles may be suitably used for a heat dissipation member. In addition, the upper limit value of the crushing strength of the aggregate boron nitride particles is not particularly limited, and may be, for example, 30 MPa or less or 20 MPa or less, for production.

The aspect ratio of primary particles constituting the aggregate boron nitride particles (a ratio of the major axis to the thickness: the length of the major axis/thickness) is preferably 11 to 18 and more preferably 12 to 15. When the aspect ratio is 11 or more, it is possible to further improve the thermal conductivity. When the aspect ratio is 18 or less, a decrease in the crushing strength can be reduced more sufficiently. The aspect ratio of the primary particles can be determined from an electron microscopic image of the aggregate boron nitride particles, and specifically, it is determined by the method described in the examples.

<Boron Nitride Powder>

One embodiment of the boron nitride powder according to the present disclosure is a boron nitride powder containing the above aggregate boron nitride particles. That is, the boron nitride powder contains aggregate boron nitride particles in which the above scaly primary hexagonal boron nitride particles are aggregated. The boron nitride powder preferably additionally satisfies all of the following conditions (D) to (F).

(D) The average particle size of the boron nitride powder is 20 to 100 μm. The average particle size of the boron nitride powder is 20 μm or more, more preferably 25 μm or more, and still more preferably 30 μm or more. In addition, the average particle size of the boron nitride powder is 100 μm or less, more preferably 90 μm or less, and still more preferably 80 μm or less. The range of the average particle size of the boron nitride powder can be adjusted within a range of 20 to 100 μm and preferably in a range of 25 to 90 μm.

When the average particle size of the boron nitride powder is too small (less than 20 μm), there may be a problem of the thermal conductivity decreasing. In addition, when the average particle size of the boron nitride powder is too large (exceeds 100 μm), the difference between the thickness of the sheet and the average particle size of the boron nitride powder becomes small, and thus it is difficult to produce the sheet in some cases.

(E) The orientation index determined from powder X-ray diffraction of the boron nitride powder is 12 or less. The orientation index of the boron nitride powder is 12 or less, preferably 10 or less, and more preferably 8 or less. When the abundance proportion of aggregate boron nitride particles in which primary particles are not substantially oriented in the aggregate boron nitride powder becomes higher, the orientation index of the boron nitride powder decreases. When the orientation index of the boron nitride powder is too large (exceeds 12), that is, it is suggested that there are many non-aggregated single particles, there is a problem of the thermal conductivity decreasing. The lower limit of the orientation index of the boron nitride powder is not particularly limited but it is generally thought to be a value of about 6.7 even if this is completely random.

“Orientation index” in this specification means a peak intensity ratio of the plane (002) to the plane (100) [I(002)/I(100)] measured using an X-ray diffraction device and specifically, it is determined by the method described in the examples.

(F) The tap density of the boron nitride powder is 0.85 g/cm³ or more. The tap density of the boron nitride powder is 0.85 g/cm³ or more and more preferably 0.90 g/cm³ or more. When the tap density of the boron nitride powder is less than 0.85 g/cm³, problems of percolation between aggregate boron nitride particles becoming insufficient and the thermal conductivity decreasing occur. The upper limit of the tap density of the boron nitride powder is not particularly limited, and in consideration of the theoretical density (2.26 g/cm³) of boron nitride, the practical upper limit value is thought to be a value of about 1.5 g/cm³.

“Tap density” in this specification means a value determined according to JIS R 1628: 1997 and specifically, it is determined by the method described in the examples.

Another embodiment of the boron nitride powder according to the present disclosure is a novel boron nitride powder that satisfies all of the above conditions (D) to (F). The boron nitride powder preferably contains the above aggregate boron nitride particles.

The thermal conductivity of the boron nitride powder according to the present disclosure can be, for example, 10 W/(m·K) or more. In addition, when dielectric breakdown is evaluated for a plurality of prepared evaluation samples containing the boron nitride powder according to the present disclosure, the proportion of the evaluation samples that undergo dielectric breakdown at a voltage of 40 kV/mm can be 5% or less. Accordingly, the boron nitride powder according to the present disclosure has both a high thermal conductivity and a high dielectric breakdown voltage. Therefore, the boron nitride powder can be suitably used as a heat dissipation member for a heat-generating electronic component (electronic component that generates heat) such as a power device, and particularly, can be suitably used as a raw material for forming a heat dissipation member of a thin film.

<Production Method for Boron Nitride Powder Containing Aggregate Boron Nitride Particles>

One embodiment of the boron nitride powder containing aggregate boron nitride particles according to the present invention is a production method for a boron nitride powder containing aggregate boron nitride particles, including a process (first process) of firing boron carbide having a carbon content of 18.0 to 21.0 mass % under a nitrogen atmosphere at 1,800° C. or higher and 0.6 MPa or more to obtain a first fired product, a process (second process) of firing the first fired product under conditions of an oxygen partial pressure of 20% or more to obtain an oxidized powder, a process (third process) of mixing the oxidized powder and a boron source, and vacuum-impregnating the oxidized powder with a boron-containing liquid phase component, a process (fourth process) of heating and firing the oxidized powder impregnated with the liquid phase component under a nitrogen atmosphere at 1,800° C. or higher to obtain a second fired product, and a process (fifth process) of pulverizing the second fired product to obtain a boron nitride powder containing aggregate boron nitride particles. The production method for a boron nitride powder can also be said to be a production method for aggregate boron nitride particles because the above aggregate boron nitride particles are prepared. The first process to the fifth process will be described below.

[First Process: Pressurizing, Nitriding and Firing Process]

In the first process, a specific boron carbide is fired under a nitrogen atmosphere at a specific firing temperature and specific pressurization conditions to obtain boron carbonitride. The first process is, for example, a process of firing boron carbide having a carbon content of 18.0 to 21.0 mass % under a nitrogen atmosphere at 1,800° C. or higher and 0.6 MPa or more to obtain a first fired product. The first fired product contains boron carbonitride and is preferably boron carbonitride.

(Boron Carbide Used in First Process)

The carbon content of boron carbide is desirably lower than a theoretical amount of 21.7 mass % determined from a composition formula B₄C. The carbon content of boron carbide may be in a range of 18.0 to 21.0 mass %. The lower limit value of the carbon content of boron carbide is preferably 19 mass % or more. The upper limit value of the carbon content of boron carbide is preferably 20.5 mass % or less. When the carbon content of boron carbide is too large (exceeds 21 mass %), this is not preferable because the content of carbon volatilized in the second process to be described below becomes too large, dense aggregate boron nitride particles cannot be produced, and a problem of the final carbon content of boron nitride becoming too large occurs. In addition, it is generally difficult to produce stable boron carbide having a carbon content of boron carbide of less than 18.0 mass % because the deviation from the theoretical composition becomes too large.

It is desirable that boron carbide not contain boric acid or free carbon impurities except for inevitable components or that it contain a small amount thereof.

The average particle size of boron carbide may be, for example, 8 to 60 μm, in consideration of an influence on the average particle size of the finally obtained aggregate boron nitride particles. The average particle size of boron carbide is preferably 8 μm or more, and more preferably 10 μm or more. When the average particle size of boron carbide is 8 μm or more, it is possible to sufficiently reduce an increase in the orientation index of the produced boron nitride powder. The upper limit value of the average particle size of boron carbide is preferably 60 μm or less, and more preferably 50 μm or less. When the average particle size of boron carbide is 60 μm or less, aggregate boron nitride particles can grow properly, and it is possible to reduce production of coarse particles.

Regarding the boron carbide, a commercially available product may be used or a separately prepared product may be used. A known preparation method can be applied as a preparation method when boron carbide is prepared, and it is possible to obtain boron carbide having a desired average particle size and carbon content.

Examples of a method for preparing boron carbide include a method in which boric acid and acetylene black are mixed and then heated at 1,800 to 2,400° C. for 1 to 10 hours in an inert gas atmosphere to obtain a boron carbide mass. In the preparation method, the obtained boron carbide mass may be appropriately subjected to, for example, pulverization, sieving, washing, removal of impurities, drying, and the like.

For mixing boric acid and acetylene black which are raw materials of boron carbide, for example, the amount of acetylene black added is suitably 25 to 40 parts by mass with respect to 100 parts by mass of boric acid.

The atmosphere when boron carbide is prepared is preferably an inert gas. Examples of inert gases include argon gas and nitrogen gas. Regarding the inert gas, argon gas, nitrogen gas and the like can be used alone or in combination. The inert gas is preferably argon gas among the above gases.

When the boron carbide mass is pulverized, a general pulverizing machine or crushing machine can be used. The pulverization time for the boron carbide mass may be, for example, about 0.5 to 3 hours. When the pulverization time for the boron carbide mass is within the above range, it is possible to obtain boron carbide having an appropriate particle size. The pulverized boron carbide is suitably sieved so that the particle size is 75 μm or less, for example, using a sieve mesh.

(Various Conditions in First Process)

The firing temperature in the first process is 1,800° C. or higher and preferably 1,900° C. or higher. In addition, the upper limit value of the firing temperature in the first process is 2,400° C. or lower, and preferably 2,200° C. or lower. The firing temperature in the first process can be adjusted within the above range, and may be, for example, 1,800 to 2,200° C.

The pressure in the first process is preferably 0.6 MPa or more and more preferably 0.7 MPa or more. In addition, the upper limit of the pressure in the first process is preferably 1.0 MPa or less and more preferably 0.9 MPa or less. The pressure in the first process can be adjusted within the above range and may be, for example, 0.7 to 1.0 MPa. When the pressure is 0.6 MPa or more, nitriding of boron carbide can proceed more sufficiently. In addition, in consideration of cost, the pressure is desirably 1.0 MPa or less, but it can be a value equal to or higher than 1.0 MPa.

The firing temperature and pressure conditions in the first process are preferably a firing temperature of 1,800 to 2,200° C. and 0.7 to 1.0 MPa. When the firing temperature is 1,800° C. and the pressure is less than 0.7 MPa, nitriding of boron carbide may not proceed sufficiently.

The atmosphere in the first process is a gas atmosphere in which the nitriding reaction of boron carbide proceeds. Examples of atmospheres in the first process include nitrogen gas and ammonia gas. Nitrogen gas, ammonia gas, and the like can be used alone or two or more thereof can be used in combination. Regarding the atmosphere in the first process, nitrogen gas is suitable in consideration of ease of nitriding and costs. The content of nitrogen gas of the atmosphere in the first process is preferably 95% (V/V) or more and more preferably 99.9% (V/V) or more.

The firing time in the first process is not particularly limited as long as nitriding proceeds sufficiently. The firing time in the first process is preferably 6 to 30 hours and more preferably 8 to 20 hours.

[Second Process: Oxidation Treatment Process]

In the second process, the boron carbonitride obtained in the first process is heated under a specific atmosphere to obtain boron carbonitride having a low carbon content. The second process is, for example, a process of firing the above first fired product under a condition of an oxygen partial pressure of 20% or more to obtain an oxidized powder. The oxidized powder contains boron carbonitride having a lower carbon content (boron carbonitride having a low carbon content) than the boron carbonitride obtained in the first process and is preferably boron carbonitride having a low carbon content.

More specifically, the second process is a process in which the boron carbonitride obtained in the first process is subjected to a heat treatment in which it is maintained in a specific temperature range to be described below for a certain time under an atmosphere with an oxygen partial pressure of 20% or more, and most of the carbon content of boron carbonitride is oxidized and decarburized to obtain boron carbonitride particles having a low carbon content. That is, in the second process, which can be called a decarburization and crystallization process, boron carbonitride is decarburized to create voids therein, the boron-containing liquid phase component used in the subsequent process can be easily impregnated and the amount of the boron-containing liquid phase component used can be reduced.

The oxygen partial pressure in the second process is 20% or more and preferably 30% or more with respect to a total pressure. Decarburization can be performed at a low temperature by treating boron carbonitride under conditions in which the oxygen partial pressure is higher than that of the atmosphere. In addition, since boron carbonitride can be oxidized at a low temperature, excess oxidation of boron carbonitride itself can be prevented.

The upper limit of the heating temperature (oxidation temperature) in the second process is preferably 950° C. or lower and more preferably 900° C. or lower. In addition, the lower limit of the heating temperature in the second process is preferably 450° C. or higher and more preferably 500° C. or higher. When the heating temperature is 450° C. or higher, decarburization of boron carbonitride can proceed more sufficiently. When the heating temperature is 950° C. or lower, it is possible to reduce oxidation of boron carbonitride itself more sufficiently.

The firing time in the second process is not particularly limited as long as oxidation proceeds sufficiently. The firing time in the second process is preferably 3 to 25 hours and more preferably 5 to 20 hours.

[Third Process: Impregnation Treatment Process]

In the third process, the boron carbonitride having a low carbon content obtained in the second process is mixed with a boron-containing component serving as a boron source, and then impregnated with a boron-containing liquid phase component. The third process is, for example, a process of mixing the oxidized powder and a boron source, and vacuum-impregnating the oxidized powder with a boron-containing liquid phase component.

More specifically, the third process may be a process in which the boron carbonitride having a low carbon content obtained in the second process is mixed with a boron-containing component serving as a boron source and then subjected to a heat treatment in which it is maintained in a specific temperature range to be described below for a certain time in a vacuum atmosphere, and thus a mixture in which the boron-containing liquid phase component and the boron carbonitride having a low carbon content are uniformly mixed and the boron-containing liquid phase component is impregnated into voids in the boron carbonitride having a low carbon content may be obtained.

In the third process, a boron source is mixed with the boron carbonitride having a low carbon content obtained in the second process as a raw material to perform additional decarburization and crystallization. Examples of boron sources include boric acid and boron oxide. Regarding the boron sources, boric acid, boron oxide, and the like can be used alone or in combination. In the third process, in addition to the boron carbonitride having a low carbon content and the boron source, as necessary, additives used in the technical field may additionally mixed in.

A formulation ratio between boron carbonitride and the boron source can be appropriately set according to the molar ratio. When boric acid or boron oxide is used as the boron source, the total amount of boric acid and boron oxide added is for example, preferably 10 to 100 parts by mass and more preferably 20 to 80 parts by mass with respect to 100 parts by mass of boron carbonitride. In addition, as necessary, an auxiliary agent may be mixed. Examples of auxiliary agents include sodium carbonate.

The firing temperature in the third process is not particularly limited as long as impregnation proceeds sufficiently. The firing temperature in the third process is preferably 200 to 500° C., more preferably 250 to 450° C., and still more preferably 300 to 400° C. When the firing temperature in the third process is 200° C. or higher, a boron-containing liquid phase component can be impregnated with boron carbonitride more sufficiently. When the firing temperature in the third process is 500° C. or lower, it is possible to reduce volatilization of the boron-containing liquid phase component.

The degree of vacuum in the third process is preferably 1 to 1,000 Pa. The treatment time in the third process is preferably 10 minutes to 2 hours and more preferably 20 minutes to 1 hour. In addition, in consideration of costs, the third process and the fourth process to be described below are desirably performed continuously, but they may be performed separately.

[Fourth Process: Crystallization Process]

In the fourth process, the mixture containing the boron-containing liquid phase component and boron carbonitride having a low carbon content obtained in the third process is heated and fired under a nitrogen atmosphere to obtain a second fired product. The fourth process is a process of heating and firing under a nitrogen atmosphere at 1,800° C. or higher to obtain a second fired product.

More specifically, in the fourth process, the mixture containing the boron-containing liquid phase component and boron carbonitride having a low carbon content obtained in the third process is heated at a specific heating rate under a nitrogen atmosphere at an atmospheric pressure or higher until a holding temperature is reached, and subjected to a heat treatment in which it is maintained in a specific temperature range for a certain time, and thus it is possible to obtain aggregate boron nitride particles in which primary particles are aggregated to form an aggregation and aggregates thereof. That is, in the fourth process, boron carbonitride can be crystallized to form scaly particles having a predetermined size and these can be uniformly aggregated to form aggregate boron nitride particles.

The pressure of the nitrogen atmosphere in the fourth process may be atmospheric pressure (barometric pressure) or may be pressurized. The pressure of the nitrogen atmosphere during pressurization is, for example, preferably 0.5 MPa or less, and more preferably 0.3 MPa or less.

In the fourth process, the heating rate when the temperature reaches a firing holding temperature may be adjusted. The heating rate when the temperature is raised to the holding temperature in the fourth process is, for example, preferably 5° C./min (that is, degrees Celsius per minute) or less, more preferably 4° C./min or less, still more preferably 3° C./min or less, and yet more preferably 2° C./min or less.

The holding temperature after the above temperature raising is 1,800° C. or higher and preferably 2,000° C. or higher. In addition, the upper limit value of the holding temperature is not particularly limited, and is preferably 2,200° C. or lower and more preferably 2,100° C. or lower. When the holding temperature is too low (lower than 1,800° C.), there is a risk of grain growth not sufficiently occurring and the thermal conductivity of the boron nitride powder decreasing. On the other hand, when the holding temperature is 1,800° C. or higher, effects in which grain growth is likely to occur favorably and the thermal conductivity is likely to be improved are exhibited.

The holding time at the holding temperature is not particularly limited as long as crystallization proceeds sufficiently. The holding time at the holding temperature is preferably longer than 0.5 hours, more preferably 1 hour or longer, still more preferably 3 hours or longer, still more preferably 5 hours or longer, and yet more preferably 10 hours or longer. In addition, the upper limit value of the holding time is preferably shorter than 40 hours, more preferably 30 hours or shorter, and still more preferably 20 hours or shorter. When the holding time is longer than 0.5 hours, it is expected that grain growth will occur favorably. In addition, when the holding time is shorter than 40 hours, it can be expected to be possible to reduce a decrease in crushing strength due to grain growth proceeding excessively and reduce industrial disadvantages due to a too long firing time. The holding time at the holding temperature can be adjusted within the above range and is preferably longer than 0.5 hours and shorter than 40 hours, and more preferably 1 to 30 hours.

[Fifth Process: Pulverizing Process]

In the fifth process, the second fired product prepared in the fourth process is pulverized to adjust the particle size. The fourth process is, for example, a process of pulverizing the above second fired product to obtain a boron nitride powder containing aggregate boron nitride particles. For pulverization, a general pulverizing machine or crushing machine can be used. Examples of pulverizing machines or crushing machines include a ball mill, a vibration mill, and a jet mill. Here, “pulverization” in this specification also includes “crushing.”

<Resin Composition: Thermally Conductive Resin Composition>

A resin composition according to one embodiment of the present disclosure includes a resin and the above boron nitride powder. The resin composition is also referred to as a thermally conductive resin composition because it can exhibit thermal conductivity. The thermally conductive resin composition can be prepared by, for example, the following method. A method for preparing a thermally conductive resin composition includes, for example, a process of mixing the above boron nitride powder with a resin. Regarding a method for preparing the thermally conductive resin composition, a method for producing a known resin composition can be used. The obtained thermally conductive resin composition can be widely used for, for example, a heat dissipation member.

(Resins)

Regarding resins used in the thermally conductive resin composition, epoxy resins, silicone resins, silicone rubber, acrylic resins, phenolic resins, melamine resins, urea resins, unsaturated polyester, cyanate resins, benzoxazine resins, fluorine resins, polyamide, polyimide (for example, polyimide, polyamideimide, polyetherimide, etc.), polyester (for example, polybutylene terephthalate, polyethylene terephthalate, etc.), polyphenylene ether, polyphenylene sulfide, fully aromatic polyester, polysulfone, polyether sulfone, liquid crystal polymers, polycarbonate, maleimide modified resins, ABS resins, AAS resins (acrylonitrile-acrylic rubber/styrene resins), AES resins (acrylonitrile/ethylene/propylene/diene rubber-styrene resins), and the like can be used.

Regarding the resins, particularly an epoxy resin (suitably a naphthalene type epoxy resin) or a silicone resin is suitable. A thermally conductive resin composition containing an epoxy resin is suitable for an insulation layer of a printed wiring board because it has excellent heat resistance and adhesive strength with respect to a copper foil circuit. In addition, the thermally conductive resin composition containing a silicone resin is suitable as a thermal interface material because it has excellent heat resistance, flexibility and adhesion to a heatsink or the like.

Specific examples of a curing agent when an epoxy resin is used include phenol novolac resins, acid anhydride resins, amino resins, and imidazoles. Among these, the curing agent is preferably imidazoles. The amount of the curing agent added is preferably 0.5 to 15 parts by mass, and more preferably 1.0 to 10 parts by mass with respect to 100 parts by mass of the raw materials (monomers).

The content of the boron nitride powder is preferably 30 to 85 volume % and more preferably 40 to 80 volume % with respect to 100 volume % of the thermally conductive resin composition. When the content of the boron nitride powder is 30 volume % or more, it is possible to further improve the thermal conductivity and it is easy to obtain more sufficient heat dissipation performance. In addition, when the content of the boron nitride powder is 85 volume % or less, it is possible to reduce the occurrence of voids and the like during molding into the heat dissipation member and it is possible to further reduce deterioration in insulation properties and mechanical strength.

<Heat Dissipation Member>

One embodiment of the heat dissipation member is a member using the above resin composition (thermally conductive resin composition). The heat dissipation member preferably contains a cured product of the above resin composition.

While some embodiments have been described above, the present disclosure is not limited to the above embodiments. In addition, detailed descriptions of the above embodiments can be applied to each other.

### EXAMPLES

The present disclosure will be described below in detail with reference to examples and comparative examples. Here, the present disclosure is not limited to the following examples.

Various measurement methods are as follows.

(1) Average Value and Standard Deviation of the Area Proportion of Primary Particles in a Cross Section of Aggregate Boron Nitride Particles

The average value and standard deviation of the area proportion of primary particles (boron nitride particles) in a cross section of aggregate boron nitride particles were measured as follows. First, as a pretreatment for observation, for the produced aggregate boron nitride powder, aggregate boron nitride particles were embedded with an epoxy resin. Next, the cross section was processed by a cross section polisher (CP) method and fixed to a sample stage. After fixing, an osmium coating was performed on the cross section.

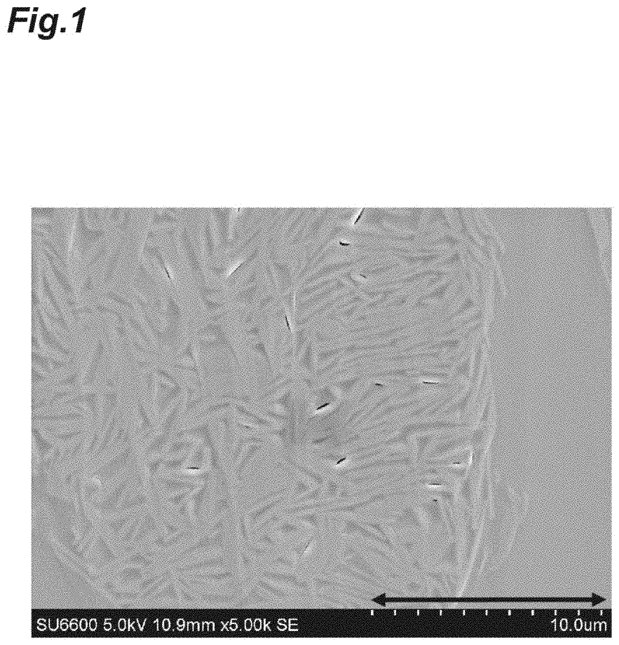

For observation of the cross section, a scanning electron microscope (“JSM-6010LA” commercially available from JEOL Ltd.) was used at an observation magnification of 2,000 to 5,000. The image of the cross section of the obtained aggregate boron nitride particles was loaded in image analysis software (“Mac-view” commercially available from Mountech Co., Ltd.), and the area proportion of primary particles (boron nitride particles) in an arbitrary region of 10 μm×10 μm in the image of the cross section of the aggregate boron nitride particles was calculated. Similarly, the area proportion of primary particles was calculated at locations of 50 field-of-views or more, and the average value was used as an average value of the area proportion of the primary particles. According to the same method, the standard deviation of the area proportion of the primary particles was calculated, and this value was used as a standard deviation of the area proportion of the primary particles. FIG. 1 shows an SEM image of the cross section of the aggregate boron nitride prepared in Example 1.

Here, regarding a parameter representing the internal structure of aggregate boron nitride particles, there is measurement of a pore diameter distribution using a mercury porosimeter or the like. However, in the results obtained by measuring a pore diameter distribution of powder, which was a cluster of aggregated particles such as aggregate boron nitride particles, it was difficult to clearly distinguish between aggregated particles and the inside of the aggregated particles. In addition, aggregated particles themselves may collapse during the pore diameter distribution measurement, which did not necessarily match the result obtained by observing the cross section of aggregated particles using an electron microscope. In addition, the results obtained by the above pore diameter distribution measurement and the insulation characteristics and heat dissipation characteristics of the obtained boron nitride powder were not necessarily correlated. Therefore, in the present disclosure, an evaluation method by image analysis as described above was used.

(2) Crushing Strength of Aggregate Boron Nitride Particles

The crushing strength was measured according to JIS R1639-5: 2007. A micro compression testing machine (“MCT-W500” commercially available from Shimadzu Corporation) was used as a measurement device. The crushing strength (σ: unit MPa) was a value calculated using a formula of σ=α×P/(π×d²) from a dimensionless number (α=2.48) that varied depending on the position in the particle, a crushing test force (P: unit N), and a particle diameter (d: unit μm). Specifically, the same measurement was performed on 20 particles or more by changing particles, and its average value was used as the crushing strength.

(3) Aspect Ratio of Primary Particles

An aspect ratio in scaly primary hexagonal boron nitride particles (a ratio of the major axis to the thickness: the length of the major axis/thickness) was determined according to the method in Japanese Unexamined Patent Publication No. 2007-308360. Specifically, 100 or more primary particles in which the major axis (overall length) and the thickness of primary particles were confirmed were selected from the electron microscopic image of the surface of aggregate boron nitride particles, and their major axes and thicknesses were measured. A ratio of the major axis to the thickness was calculated from the measurement results and its average value was used as the aspect ratio of the primary particles.

(4) Average Particle Size of Boron Nitride Powder

The average particle size of the boron nitride powder was measured using a laser diffraction scattering method particle size distribution measurement device (“LS-13 320” commercially available from Beckman Coulter, Inc.) according to ISO 13320: 2009. However, the sample was measured without a homogenizer before the measurement process. The average particle size was a particle size of 50% (median diameter, d50) of the cumulative value in the cumulative particle size distribution. When the particle size distribution was measured, water was used as a solvent in which the aggregate was dispersed and hexamethaphosphate was used as a dispersant. In this case, 1.33 was used for the refractive index of water and a value of 1.80 was used as the refractive index of the boron nitride powder.

(5) Orientation Index of Boron Nitride Powder

The orientation index of the boron nitride powder was measured using an X-ray diffraction device (“ULTIMA-IV” commercially available from Rigaku Corporation). A sample was prepared by solidifying the boron nitride powder on the attached glass cell, X-rays were emitted to the sample, and a peak intensity ratio of the plane (002) to the plane (100) [I(002)/I(100)] was calculated and this was evaluated as an orientation index.

(6) Tap Density of Boron Nitride Powder

The tap density of the boron nitride powder was measured according to JIS R 1628: 1997. A commercially available device was able to be used for measurement. Specifically, the boron nitride powder was filled into a 100 cm³ dedicated container, the bulk density after tapping was performed under conditions of a tapping time of 180 seconds, a tapping frequency of 180, and a tapping lift of 18 mm was measured, and the obtained value was used as the tap density.

(7) Thermal Conductivity

The thermal conductivity was measured using a sheet produced from the thermally conductive resin composition containing the boron nitride powder as a measurement sample. The thermal conductivity (H: unit W/(m·K)) was calculated based on a formula of H=A×B×C from a thermal diffusivity (A: unit m²/sec), a density (B: unit kg/m³), and a specific heat capacity (C: unit J/(kg·K)).

The thermal diffusivity A was determined by preparing a sample obtained by processing the above sheet into a width of 10 mm×10 mm×a thickness of 0.3 mm and performing a laser flash method thereon. A xenon flash analyzer (“LFA447NanoFlash” commercially available from NETZSCH) was used as a measurement device. The density B was determined using the Archimedes' method. The specific heat capacity C was determined using DSC (“ThermoPlusEvo DSC8230” commercially available from Rigaku Corporation). The passing value of the thermal conductivity was set to 10 W/(m·K) or more and 12 W/(m·K) or more was regarded as excellent.

(8) Insulation Properties: Dielectric Breakdown Voltage

The dielectric breakdown voltage of the produced substrate was measured using a pressure resistance tester (“TOS 8650” commercially available from Kikusui Electronics Corporation) according to HS C 6481: 1996. The measurement was performed on 100 samples. When the thickness of the cured layer of the resin composition containing the boron nitride powder was 200 μm, if the proportion of the sample that underwent dielectric breakdown when a voltage of 40 kV/mm was applied was 5% or less, it was evaluated as “A (satisfactory),” if the proportion was 5 to 20%, it was evaluated as “B,” and if the proportion was 20% or more, it was evaluated as “C (unacceptable).”

(9) Measurement of Carbon Content of Boron Carbide

The carbon content of boron carbide was measured using a carbon analyzing device (“Model IR-412” commercially available from LECO).

### Example 1

In Example 1, a boron nitride powder was prepared as described below. In addition, the prepared boron nitride powder was filled into a resin, and evaluation was performed.

(Boron Carbide Synthesis)

100 parts by mass of boric acid (orthoboric acid commercially available from Nippon Denko Co., Ltd.) and 35 parts by mass of acetylene black (product name: HS100 commercially available from Denka Co., Ltd.) were mixed using a Henschel mixer and the obtained mixture was then filled into a graphite crucible. Then, the mixture was heated using an arc furnace under conditions of an argon atmosphere and 2,200° C. for 5 hours, and boron carbide (B₄C) was synthesized.

The synthesized boron carbide mass was pulverized with a ball mill for 1 hour and sieved using a sieve mesh so that the particle size was 75 μm or less. Then, boron carbide was additionally washed with an aqueous nitric acid solution to remove impurities such as iron, and filtration and drying were performed to prepare a boron carbide powder having an average particle size of 20 μm. The carbon content of the obtained boron carbide powder was 20.0 mass %.

(First Process)

The synthesized boron carbide was filled into a boron nitride crucible, and the boron nitride was then heated using a resistance heating furnace under conditions of a nitrogen gas atmosphere, 2,000° C., and 9 atm (0.8 MPa) for 10 hours to prepare boron carbonitride (B₄CN₄). The carbon content of the obtained boron carbonitride was 9.9 mass %.

(Second Process)

The synthesized boron carbonitride was filled into an alumina crucible and the boron carbonitride was then heated using a muffle furnace under conditions of an atmosphere with an oxygen partial pressure of 40% and 700° C. for 5 hours, and thus boron carbonitride having a lower carbon content than the boron carbonitride obtained in the above first process was obtained. The carbon content of the boron carbonitride having a low carbon content was 2.5 mass %.

(Third Process)

100 parts by mass of the synthesized boron carbonitride and 45 parts by mass of boric acid were mixed using a Henschel mixer and the obtained mixture was then filled into a boron nitride crucible. Then, the mixture was maintained under conditions of a vacuum atmosphere of 100 Pa and 420° C. for 1 hour using a resistance heating furnace.

(Fourth Process)

Following the impregnation treatment process in a vacuum, nitrogen gas was introduced into the resistance heating furnace, the temperature was raised from room temperature to 1,000° C. at a heating rate of 10° C./min under conditions of 0.3 MPa and a nitrogen gas atmosphere, and then the heating rate was changed to 2° C./min and the temperature was raised from 1,000° C. to 2,000° C. The above mixture was additionally heated at a holding temperature of 2,000° C. and for a holding time of 5 hours and thus an assembly of aggregate boron nitride particles in which primary particles were aggregated to form an aggregation was synthesized.

(Fifth Process)

The cluster of the synthesized aggregate boron nitride particles was crushed using a Henschel mixer and then classified with a nylon sieve having a mesh size of 100 μm using a sieve mesh, and thus a boron nitride powder having an average particle size of 45 μm was produced. The porosity of the obtained boron nitride powder was 48% and a specific surface area was 4.2 m²/g. Here, the porosity was determined by measuring a total pore volume using a mercury porosimeter according to JIS R 1655.

(Preparation of Resin Composition: Filling into Resin)

Characters of the obtained boron nitride powder as a filler with respect to a resin were evaluated. A mixture containing 100 parts by mass of a naphthalene type epoxy resin (product name: HP4032 commercially available from DIC) and 10 parts by mass of a curing agent (imidazoles, product name: 2E4MZ-CN commercially available from Shikoku Chemical Corporation) was prepared. The boron nitride powder was additionally mixed so that the boron nitride powder was 50 volume % with respect to 100 volume % of the mixture to prepare a slurry. The slurry was applied onto a PET sheet so that the thickness was 0.3 mm to form a coating film. Then, the coating film was decompressed and defoamed for 10 minutes under a reduced pressure of 500 Pa. Next, the coating film was press-heated and pressurized for 60 minutes under conditions of a temperature of 150° C. and a pressure of 160 kg/cm², and a sheet with a thickness of 0.3 mm was formed.

The following Table 1 and Table 2 show measured values and evaluation results of other examples and comparative examples.

### Example 2

In Example 2, a boron nitride powder was produced in the same manner as in Example 1 except that the pulverization time during preparation of boron carbide was changed to 30 minutes to prepare “boron carbide having an average particle size of 40 μm.”

### Example 3

In Example 3, a boron nitride powder was produced in the same manner as in Example 1 except that the pulverization time during preparation of boron carbide was changed to 1.5 hours to prepare “boron carbide having an average particle size of 12 μm.”

### Example 4

In Example 4, a boron nitride powder was produced in the same manner as in Example 1 except that the holding time in the second process was changed to 9 hours to obtain “boron carbonitride having a low carbon content (carbon content: 0.8 mass %).”

### Example 5

In Example 5, a boron nitride powder was produced in the same manner as in Example 1 except that the holding time in the second process was changed to 0.5 hours to obtain “boron carbonitride having a low carbon content (carbon content: 4.5 mass %).”

### Example 6

In Example 6, a boron nitride powder was produced in the same manner as in Example 1 except that the firing temperature in the third process was changed to 200° C.

### Example 7

In Example 7, a boron nitride powder was produced in the same manner as in Example 1 except that the firing temperature in the third process was changed to 350° C.

### Comparative Example 1 and Comparative Example 2

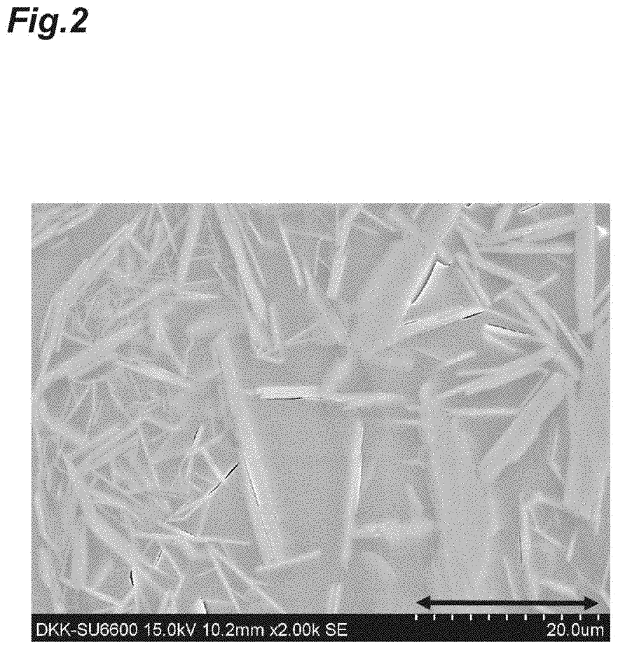

Two types of commercially available boron nitride powder (commercial products a and b) were evaluated in the same manner as in Examples 1 to 7. In the table, the results of the commercial product a are shown in Comparative Example 1, and the results of the commercial product b are shown in Comparative Example 2. In addition, FIG. 2 shows an SEM image of Comparative Example 1. In Comparative Example 1, the porosity of the boron nitride powder was 38%, and the specific surface area was 3.2 m²/g.

### Comparative Example 3

In Comparative Example 3, a boron nitride powder was produced in the same manner as in Example 1 except that the second process and the third process were not performed, before the fourth process, 100 parts by mass of boron carbonitride and 200 parts by mass of boric acid were mixed using a Henschel mixer, and the obtained mixture was then filled into a boron nitride crucible.

TABLE 1

| | | Example | Example | Example | Example | Example | Example | Example |
|---|---|---|---|---|---|---|---|---|
| | | 1 | 2 | 3 | 4 | 5 | 6 | 7 |
| Aggregate | Average | 60 | 60 | 60 | 76 | 54 | 60 | 60 |
| boron | value [%] | | | | | | | |
| nitride | of area | | | | | | | |
| particles | proportion | | | | | | | |
| | of primary | | | | | | | |
| | particles in | | | | | | | |
| | cross | | | | | | | |
| | section | | | | | | | |
| | Standard | 9 | 9 | 9 | 9 | 9 | 20 | 5 |
| | deviation | | | | | | | |
| | of area | | | | | | | |
| | proportion | | | | | | | |
| | of primary | | | | | | | |
| | particles in | | | | | | | |
| | cross | | | | | | | |
| | section | | | | | | | |
| | Crushing | 13.1 | 13.6 | 13.1 | 13.5 | 12.5 | 12.7 | 13.3 |
| | strength | | | | | | | |
| | [MPa] | | | | | | | |
| | Aspect | 13 | 14 | 13 | 13 | 13 | 13 | 14 |
| | ratio of | | | | | | | |
| | primary | | | | | | | |
| | particles | | | | | | | |
| Boron | Average | 45 | 80 | 25 | 45 | 45 | 45 | 45 |
| nitride | particle | | | | | | | |
| powder | size [μm] | | | | | | | |
| | Orientation | 7 | 7 | 7 | 7 | 7 | 7 | 7 |
| | index | | | | | | | |
| | Tap | 0.90 | 0.90 | 0.90 | 1.05 | 0.90 | 0.90 | 0.90 |
| | density | | | | | | | |
| | [g/cm³] | | | | | | | |

| | | | | | | | |
|---|---|---|---|---|---|---|---|
| Insulation properties | A | A | A | A | A | A | A |
| Thermal conductivity | 13 | 13 | 12 | 13 | 14 | 11 | 13 |
| [W/(m · K)] | | | | | | | |

TABLE 2

| | | Compar- | Compar- | Compar- |
|---|---|---|---|---|
| | | ative | ative | ative |
| | | Example 1 | Example 2 | Example 3 |
| Aggregate | Average value | 38 | 60 | 51 |
| boron | [%] of area | | | |
| nitride | proportion of | | | |
| particles | primary particles | | | |
| | in cross section | | | |
| | Standard | 25 | 40 | 26 |
| | deviation of area | | | |
| | proportion of | | | |
| | primary particles | | | |
| | in cross section | | | |
| | Crushing strength | 3.7 | 6.3 | 11.3 |
| | [MPa] | | | |
| | Aspect ratio of | 22 | 9 | 14 |
| | primary particles | | | |
| Boron | Average particle | 70 | 35 | 45 |
| nitride | size [μm] | | | |
| powder | Orientation index | 8 | 10 | 7 |
| | Tap density | 0.60 | 0.80 | 0.80 |
| | [g/cm³] | | | |

| | | | |
|---|---|---|---|
| Insulation properties | C | C | B |
| Thermal conductivity \|W/(m · K)] | 10 | 8 | 12 |

### INDUSTRIAL APPLICABILITY

The present disclosure can provide a boron nitride powder having excellent thermal conductivity and dielectric breakdown characters and method for producing the same. The boron nitride powder can be added to the resin composition, and for example, can be used by filling into the resin composition of the insulation layer of the printed wiring board and the thermal interface material. The resin composition can be used by being cured. The resin composition containing the boron nitride powder of the present disclosure and a cured product thereof can be used, for example, a heat member. The heat dissipation member can be widely used, and for example, can be used as a heat dissipation member for an electronic component that generates heat such as a power device.

1. Aggregate boron nitride particles in which primary hexagonal boron nitride particles are aggregated,
wherein an average value of an area proportion of the primary particles in a cross section is 45% or more,
a standard deviation of the area proportion of the primary particles in a cross section is less than 25, and
a crushing strength is 8.0 MPa or more.

2. The aggregate boron nitride particles according to claim 1,
wherein the average value of the area proportion of the primary particles in a cross sections is 50 to 85%.

3. The aggregate boron nitride particles according to claim 1,
wherein the standard deviation of the area proportion of the primary particles in a cross section is 20 or less.

4. The aggregate boron nitride particles according to claim 1,
wherein the standard deviation of the area proportion of the primary particles in a cross section is 15 or less.

5. A boron nitride powder comprising the aggregate boron nitride particles according to claim 1.

6. A boron nitride powder having an average particle size of 20 to 100 μm, an orientation index of 12 or less determined from powder X-ray diffraction, and a tap density of 0.85 g/cm³ or more.

7. A production method for a boron nitride powder containing aggregate boron nitride particles, comprising:
firing boron carbide having a carbon content of 18.0 to 21.0 mass % under a nitrogen atmosphere at 1,800° C. or higher and 0.6 MPa or more to obtain a first fired product;
firing the first fired product under a condition of an oxygen partial pressure of 20% or more to obtain an oxidized powder;
mixing the oxidized powder and a boron source and vacuum-impregnating the oxidized powder with a boron-containing liquid phase component;
heating and firing the oxidized powder impregnated with the liquid phase component under a nitrogen atmosphere at 1,800° C. or higher to obtain a second fired product; and
pulverizing the second fired product to obtain a boron nitride powder containing an aggregate boron nitride powder.

8. A resin composition comprising the boron nitride powder according to claim 5, and a resin.

9. A heat dissipation member comprising a cured product of the resin composition according to claim 8.
